(19) United States
(12) Patent Application Publication
(10) Pub. No.: US 2024/0283215 A1
(43) Pub. Date: Aug. 22, 2024

(54) SUBCARRIER, LASER MODULE, AND OPTICAL ENGINE MODULE

(71) Applicant: TDK CORPORATION, Tokyo (JP)

(72) Inventors: Takashi HONDA, Tokyo (JP); Takashi AOYAGI, Tokyo (JP); Makoto FUKUDA, Tokyo (JP); Tsuyoshi KOMAKI, Tokyo (JP); Ryohei FUKUZAKI, Hong Kong (CN)

(73) Assignee: TDK CORPORATION, Tokyo (JP)

(21) Appl. No.: 18/524,007

(22) Filed: Nov. 30, 2023

(30) Foreign Application Priority Data
Feb. 17, 2023 (JP) 2023-023744

(51) Int. Cl. H01S 5/02315; H01S 5/00

(52) U.S. Cl. CPC H01S 5/02315; H01S 5/0071

(57) ABSTRACT

What is provided is a subcarrier and a laser module in which, when an optical semiconductor element is formed on the subcarrier, blocking of an irradiation surface of the optical semiconductor element by a structure formed by melting is curbed.

This subcarrier is a subcarrier for a laser module including a wafer portion that is constituted of a base and a protective layer formed on a surface of the base, a first metal layer that is formed on the protective layer, a eutectic layer that is formed on the first metal layer, and a second metal layer that is formed on the eutectic layer. The wafer portion has a recessed portion formed in a region overlapping the eutectic layer in a width direction, that is, a region on an outward side of the first metal layer in a longitudinal direction.

### BACKGROUND OF THE INVENTION

### Field of the Invention

The present invention relates to a subcarrier, a laser module, and an optical engine module.

### Description of Related Art

With increases in data traffic, optical communication systems and various optical devices around us using an optical communication system are becoming multifunctional. Recently, multifunctional and compact optical devices have been studied due to the demand for multifunctional and high-density devices.

In recent years, a technology of silicon photonics, in which a light emitting element and a light receiving element are integrated in a silicon waveguide, has progressed and is being used in optical communication systems. Planar lightwave circuits (PLC) performing optical signal processing such as multiplexing, demultiplexing, and wavelength selection are one example of typical silicon waveguides used in optical communication systems.

In addition to optical communication systems, for example, regarding wearable devices, small-sized projectors, and the like around us as well, there is a demand for multifunctional and compact optical devices that exhibit a plurality of functions in accordance with the purpose of use and can be carried around in their entirety.

XR glasses such as augmented reality (AR) glasses and virtual reality (VR) glasses are expected to be compact wearable devices. Regarding wearable devices such as AR glasses and VR glasses, the key to popularization thereof is miniaturization to the extent that they are equipped with every function in an ordinary size of eyeglasses.

Patent Document 1 discloses a laser diode element in which a chip including the laser diode element emitting laser light is bonded to a sub-mount using a melted AuSn solder.

### PATENT DOCUMENT

[Patent Document 1] Japanese Unexamined Patent Application, First Publication No. 2016-001289

### SUMMARY OF THE INVENTION

However, in the laser diode element in Patent Document 1, the chip including the laser diode element emitting a laser is bonded to the sub-mount using a melted AuSn solder, and if the melted AuSn solder sticks out on an irradiation surface of the laser diode element, laser light is blocked by the structure of melted AuSn.

The present invention has been made in consideration of the foregoing circumstances, and an object thereof is to provide a subcarrier, a laser module, and an optical engine module and XR glasses including the same, in which when an optical semiconductor element is formed on the subcarrier, blocking of an irradiation surface of the optical semiconductor element by a structure formed by melting is curbed and laser light is controlled to pass through a desired optical path.

In order to resolve the foregoing problems, the present invention provides the following means.
(1) A subcarrier according to an aspect of the present invention is a subcarrier for a laser module including a wafer portion that is constituted of a base and a protective layer formed on a surface of the base, a first metal layer that is formed on the protective layer, a eutectic layer that is formed on the first metal layer, and a second metal layer that is formed on the eutectic layer. The wafer portion has a recessed portion formed in a region overlapping the eutectic layer in a width direction and outside the first metal layer in a longitudinal direction.
(2) In the subcarrier according to the foregoing (1), in a plan view in a lamination direction, end surfaces of the first metal layer and the eutectic layer in the longitudinal direction may overlap the recessed portion.
(3) In the subcarrier according to the foregoing (1) or (2), a depth of the recessed portion from a surface of the protective layer may be 10 μm or longer.
(4) A laser module according to another aspect of the present invention includes the subcarrier according to one of the foregoing (1) to (3), and an optical semiconductor element formed on the second metal layer which is configured to irradiate laser light in the longitudinal direction. In a plan view in a lamination direction, a laser light irradiation surface of the optical semiconductor element overlaps the recessed portion.
(5) In the laser module according to the foregoing (4), the first metal layer and the eutectic layer may be covered by the optical semiconductor element.
(6) In the laser module according to the foregoing (4) or (5), in a laser light irradiation direction of the optical semiconductor element, a distance between an end portion of the first metal layer and an end portion of the optical semiconductor element may be 1 μm or longer.
(7) An optical engine module according to another aspect of the present invention includes the laser module according to any one of the foregoing (4) to (6), and an optical scanning mirror that performs scanning with light emitted from the laser module.

According to the present invention, it is possible to provide a subcarrier and a laser module, in which when an optical semiconductor element is formed on the subcarrier, blocking of an irradiation surface of the optical semiconductor element by a structure formed by melting is curbed.

### BRIEF DESCRIPTION OF THE DRAWINGS

FIG. 1 is an explanatory perspective view of a structure of a laser module according to an embodiment of the present invention.

FIG. 2 is a cross-sectional view of an incidence surface of a PLC of the laser module illustrated in FIG. 1.

FIG. 3 is a plan view of a part of the laser module illustrated in FIG. 1.

FIG. 4 is an explanatory cross-sectional view of a structure of a subcarrier and a semiconductor light emitting element provided in the laser module in FIG. 1.

FIG. 5 is an explanatory cross-sectional view of a structure of the subcarrier and the semiconductor light emitting element provided in the laser module in FIG. 1 and is a cross-sectional view illustrating a cross section in a direction different from that in FIG. 2.

FIG. 6 is an explanatory view of a method for manufacturing a subcarrier according to the embodiment of the present invention.

FIG. 7 is an explanatory view of the method for manufacturing a subcarrier according to the embodiment of the present invention and is a view illustrating a condition in which a recessed portion is formed in a wafer portion.

FIG. 8 is an explanatory view of the method for manufacturing a subcarrier according to the embodiment of the present invention and is a view illustrating a condition in which an LD is bonded to a base.

FIG. 9 is a top view illustrating a modification example of the laser module in in FIG. 1.

FIG. 10 is a perspective view illustrating the modification example of the laser module in FIG. 1.

FIG. 11 is a plan view of a packaged integrated laser module.

FIG. 12 is a cross-sectional view of the laser module in FIG. 11.

FIG. 13 is a plan view of a state in which a cover of the laser module in FIG. 11 is removed.

FIG. 14 is a side view of the laser module in FIG. 11 viewed from an emission portion side.

FIG. 15 is a perspective view illustrating a form when the laser module in FIG. 11 is in use.

FIG. 16 is an explanatory conceptual view of XR glasses according to the embodiment of the present invention.

FIG. 17 is a conceptual view illustrating a condition in which an image is directly projected onto the retina by laser light emitted from the laser module according to the embodiment of the present invention.

### DETAILED DESCRIPTION OF THE INVENTION

Hereinafter, an embodiment will be described in detail suitably with reference to the drawings. In drawings used in the following description, in order to make characteristics easy to understand, characteristic portions may be illustrated in an enlarged manner for the sake of convenience, and dimensional ratios or the like of each constituent element may differ from actual values thereof. Materials, dimensions, and the like illustrated in the following description are merely exemplary examples. The present invention is not limited thereto and can be suitably changed and performed within a range in which the effects of the present invention are exhibited. In the present embodiment, formation of a certain layer on a different layer is not limited to an example of being directly formed on the different layer and includes a constitution of being formed thereon with another layer therebetween.

### [Laser Module]

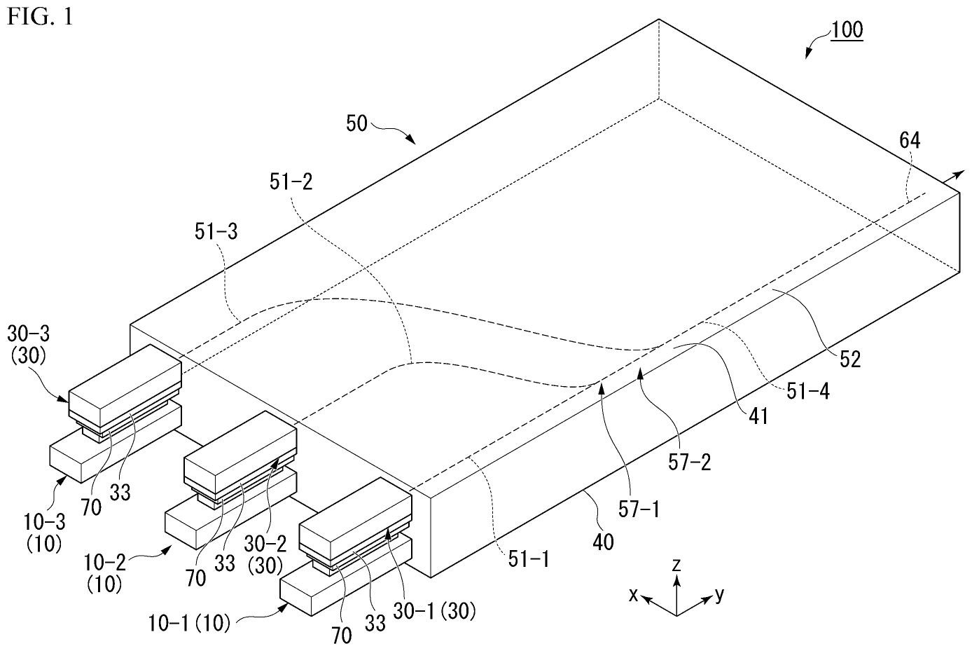

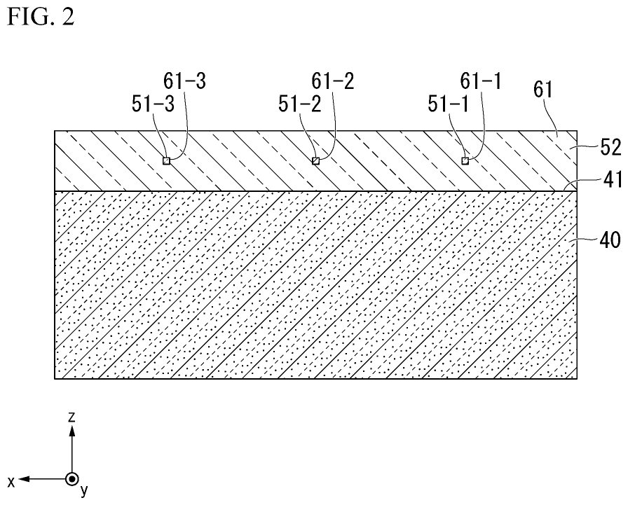

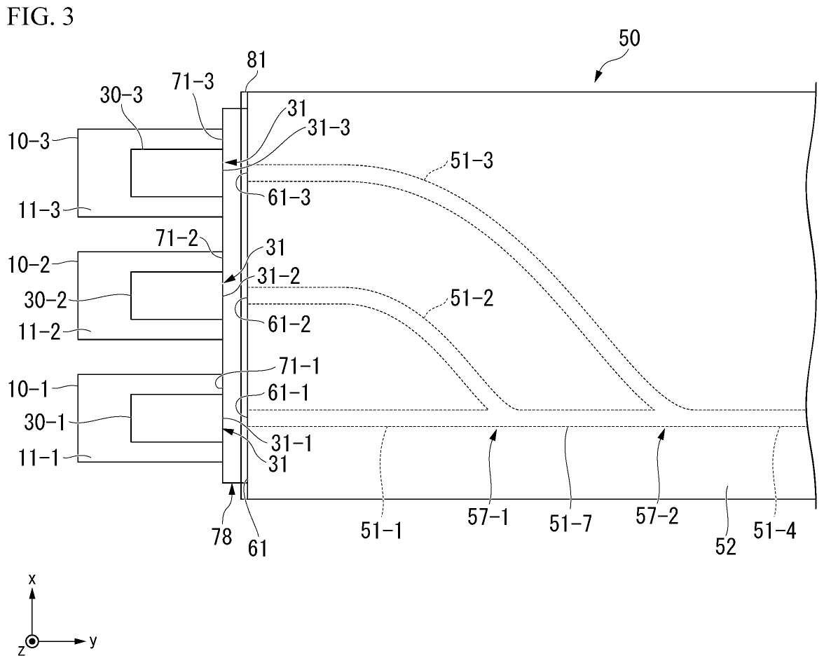

FIG. 1 is an explanatory perspective view of a structure of a laser module according to an embodiment of the present invention. FIG. 2 is a cross-sectional view of an incidence surface of a PLC of the laser module illustrated in FIG. 1, and FIG. 3 is a plan view of a part of the laser module illustrated in FIG. 1.

A laser module 100 illustrated in FIG. 1 includes subcarriers 10 which will be described below in detail, optical semiconductor elements (LDs) 30 respectively bonded to upper surfaces 11 of the subcarriers 10 with metal layers 70 therebetween, a substrate 40 formed in an in-plane direction of the subcarriers 10, and an optical waveguide (PLC) 50 provided on an upper surface of the substrate 40. In the LDs 30, growth layers 33 are formed on surfaces thereof on a side closer to the subcarriers 10. The LDs 30 are formed on second metal layers 76 (which will be described below in detail) of the metal layers 70. The LDs are configured to irradiate laser light in a longitudinal direction (y direction). In the laser module illustrated in the figures, the LDs 30 are provided such that irradiation can be performed with laser light in a positive y direction. For example, a reflection surface is formed on surfaces on both sides of the LDs 30 in the y direction. For example, the intensity of laser light emitted due to induced emission is enhanced by forming a reflection surface having a low reflectance on an end surface in the positive y direction that is an irradiation direction of laser light, and forming a reflection surface having a high reflectance in a negative y direction.

The laser module 100 is a multiplexer for multiplexing rays of light of colors, such as red (R), green (G), and blue (B) that are three primary colors of light. For example, the laser module 100 can be applied as a multiplexer mounted in a head mounted display. The optical semiconductor elements (LDs) 30 (light sources used) are not limited to red (R), green (G), and blue (B). In the present embodiment, regarding the optical semiconductor elements (LDs) 30 of three primary colors of light described as an example, various kinds of commercially available laser elements for red light, green light, blue light, and the like can be used. Selection need only be suitably made in accordance with the desired purpose. For example, light having a peak wavelength of 610 nm to 750 nm can be used as red light, light having a peak wavelength of 500 nm to 560 nm can be used as green light, and light having a peak wavelength of 435 nm to 480 nm can be used as blue light.

For example, each of the LDs 30 is a laminate in which a P-positive contact layer, a current blocking layer, a P-positive cladding layer, an N-negative cladding layer, and an N-negative semiconductor substrate are stacked in this order sequentially from a side closer to a wafer portion 20 and is controlled and operated such that the surface on a side closer to the wafer portion 20 has a high potential and the surface on a side away from the wafer portion 20 has a low potential.

The laser module 100 includes an LD 30-1 emitting red light, an LD 30-2 emitting green light, and an LD 30-3 emitting blue light. The LDs 30-1, 30-2, and 30-3 are disposed with an interval therebetween in a direction substantially orthogonal to an emission direction of light emitted from each of the LDs and are provided on the upper surfaces of the respective subcarriers 10. As will be described below in detail, the LD 30-1, the LD 30-2, and the LD 30-3 are respectively provided on upper surfaces 11-1, 11-2, and 11-3 of subcarriers 10-1, 10-2, and 10-3. Hereinafter, regarding the reference sign Z of an arbitrary constituent element of the laser module 100, details common to the constituent elements of the reference signs Z-1, Z-2, and so on to Z-K may be collectively described with the reference sign Z. The sign K described above is a natural number equal to or larger than 2.

Needless to say, light other than red (R), green (G), and blue (B) described in the present embodiment can also be used, and there is no need for a mounting order of red (R), green (G), and blue (B) which have been described using the drawings to be this order and can be suitably changed.

The substrate 40 is constituted using silicon (Si). The PLC 50 is produced on an upper surface 41 such that it is integrated with the substrate 40 by semiconductor processing including known photolithography and dry etching used when fine structures such as integrated circuits are formed. As illustrated in FIGS. 1 and 2, the PLC 50 is provided with a plurality of cores 51-1, 51-2, and 51-3 as many as the LDs 30-1, 30-2, and 30-3, and a cladding 52 surrounding the cores 51-1, 51-2, and 51-3. The thickness of the cladding 52 and the dimensions of the cores 51-1, 51-2, and 51-3 in a width direction are not particularly limited. For example, the cores 51-1, 51-2, and 51-3 having dimensions of approximately several microns in the width direction are arranged in the cladding 52 having a thickness of approximately 50 μm.

For example, the cores 51-1, 51-2, and 51-3 and the cladding 52 are constituted using quartz. The refractive indices of the cores 51-1, 51-2, and 51-3 are higher than the refractive index of the cladding 52 by a predetermined value. Due to this, light incident on each of the cores 51-1, 51-2, and 51-3 propagates through each of the cores while being totally reflected on the boundary surfaces between each of the cores and the cladding 52. For example, the cores 51-1, 51-2, and 51-3 are doped with impurities such as germanium (Ge) in an amount corresponding to the predetermined value described above.

Hereinafter, the emission direction of light emitted from the LDs 30 will be regarded as a y direction. A direction which is orthogonal to the y direction within a plane including the y direction and in which the LDs 30-1, 30-2, and 30-3 are disposed with an interval therebetween will be regarded as an x direction. A direction which is orthogonal to the x direction and the y direction and is directed toward the LDs 30 from the subcarriers 10 will be regarded as a z direction. On an incidence surface 61 of the PLC 50, the cores 51-1, 51-2, and 51-3 are disposed along an optical axis of light emitted from the LDs 30-1, 30-2, and 30-3 in the x direction and the z direction.

As illustrated in FIG. 1, the cores 51-1, 51-2, and 51-3 are brought together in front of the side reaching an emission surface 64 of the PLC 50. That is, the cores 51-1, 51-2, and 51-3 are focused as they go forward in the y direction and merge into one core 51-4. It is preferable that each of the cores 51-1, 51-2, and 51-3 be focused on the core 51-4 with a radius of curvature equal to or larger than a predetermined radius of curvature.

As illustrated in FIG. 3, the incidence surface 61 of the PLC 50 is disposed in a manner of facing emission surfaces 31 of the LDs 30. Specifically, an emission surface 31-1 of the LD 30-1 faces an incidence surface 61-1 of the core 51-1. In the x direction and the z direction, the optical axis of red light emitted from the LD 30-1 and the center on the incidence surface 61-1 substantially overlap each other. Similarly, an emission surface 31-2 of the LD 30-2 faces an incidence surface 61-2 of the core 51-2. In the x direction and the z direction, the optical axis of green light emitted from the LD 30-2 and the center on the incidence surface 61-2 substantially overlap each other. An emission surface 31-3 of the LD 30-3 faces an incidence surface 61-3 of the core 51-3. In the x direction and the z direction, the optical axis of blue light emitted from the LD 30-3 and the center on the incidence surface 61-3 substantially overlap each other. Due to such a constitution and disposition, at least a part of red light, green light, and blue light emitted from the LDs 30-1, 30-2, and 30-3 can be incident on the cores 51-1, 51-2, and 51-3.

As illustrated in FIG. 1, red light, green light, and blue light emitted from the LDs 30-1, 30-2, and 30-3 are respectively incident on the cores 51-1, 51-2, and 51-3 and then propagate through each of the cores. The cores 51-1 and 51-2 and red light and green light propagating through these cores meet at a predetermined merge position 57-1 (refer to FIG. 3) behind a merge position 57-2 in the y direction. A core 51-7 (refer to FIG. 3) where the cores 51-1 and 51-2 have merged and the core 51-3 and red light, green light, and blue light propagating through these cores meet at the merge position 57-2. Red light, green light, and blue light which have been concentrated at the merge position 57-2 propagate through the core 51-4 and arrive at the emission surface 64. For example, three-color light emitted from the emission surface 64 is used as signal light or the like in accordance with the purpose of use of the laser module 100.

As illustrated in FIG. 3, the incidence surface 61 of the PLC 50 is disposed in a manner of facing the emission surfaces 31 of the LDs 30. Specifically, the emission surface 31-1 of the LD 30-1 faces the incidence surface 61-1 of the core 51-1. In the x direction and the z direction, the optical axis of red light emitted from the LD 30-1 and the center on the incidence surface 61-1 substantially overlap each other. Similarly, the emission surface 31-2 of the LD 30-2 faces the incidence surface 61-2 of the core 51-2. In the x direction and the z direction, the optical axis of green light emitted from the LD 30-2 and the center on the incidence surface 61-2 substantially overlap each other. The emission surface 31-3 of the LD 30-3 faces the incidence surface 61-3 of the core 51-3. In the x direction and the z direction, the optical axis of blue light emitted from the LD 30-3 and the center on the incidence surface 61-3 substantially overlap each other. Due to such a constitution and disposition, at least a part of red light, green light, and blue light emitted from the LDs 30-1, 30-2, and 30-3 can be incident on the cores 51-1, 51-2, and 51-3.

As illustrated in FIGS. 1 and 3, red light, green light, and blue light emitted from the LDs 30-1, 30-2, and 30-3 are respectively incident on the cores 51-1, 51-2, and 51-3 and then propagate through each of the cores. The cores 51-1 and 51-2 and red light and green light propagating through these cores meet at the predetermined merge position 57-1 (refer to FIG. 3) behind the merge position 57-2 in the y direction. The core 51-7 (refer to FIG. 3) where the cores 51-1 and 51-2 have merged and the core 51-3 and red light, green light, and blue light propagating through these cores meet at the merge position 57-2. Red light, green light, and blue light which have been concentrated at the merge position 57-2 propagate through the core 51-4 and arrive at the emission surface 64. For example, three-color light emitted from the emission surface 64 is used as signal light or the like in accordance with the purpose of use of the laser module 100.

The subcarriers 10 and the substrate 40 are bonded to each other by various kinds of metal layers. For example, the subcarriers 10 and the substrate 40 are bonded to each other by AuSn or the like. FIG. 3 illustrates a condition in which the subcarriers 10 and the substrate 40 are bonded to each other by a bonding layer 78. The bonding layer 78 may be constituted of one layer or a plurality of layers. That is, a plurality of metal layers may be formed between the subcarriers 10 and the substrate 40 in the y direction. In addition, an antireflection film 81 may be provided on an end surface of the PLC 50 on a side closer to the subcarriers 10. For example, the antireflection film 81 is integrally molded with the end surfaces of the substrate 40 and the PLC 50. For example, the antireflection film 81 is a multilayer film formed by alternately laminating a plurality of kinds of dielectrics with a predetermined thickness corresponding to wavelengths of red light, green light, and blue light (incident light). Examples of dielectrics used as the antireflection film 81 include titanium oxide (TiO₂), tantalum oxide (Ta₂O₅), silicon oxide (SiO₂), and aluminum oxide (Al₂O₃).

The emission surfaces 31 of the LDs 30 and the incidence surface 61 of the PLC 50 are disposed with a predetermined interval therebetween. The incidence surface 61 faces the emission surfaces 31, and there is a gap between the emission surfaces 31 and the incidence surface 61 in the y direction. Since the laser module 100 is exposed to the air, the gap is filled with air.

### <Subcarrier>

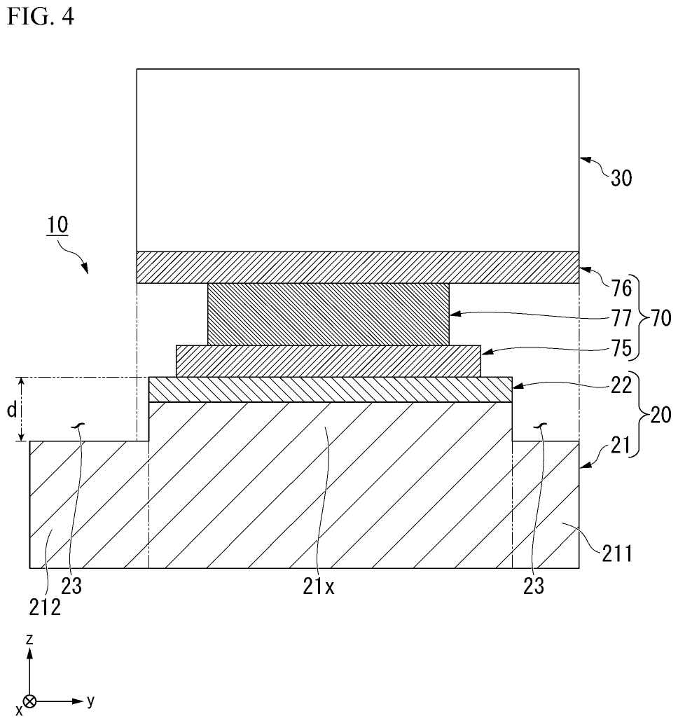

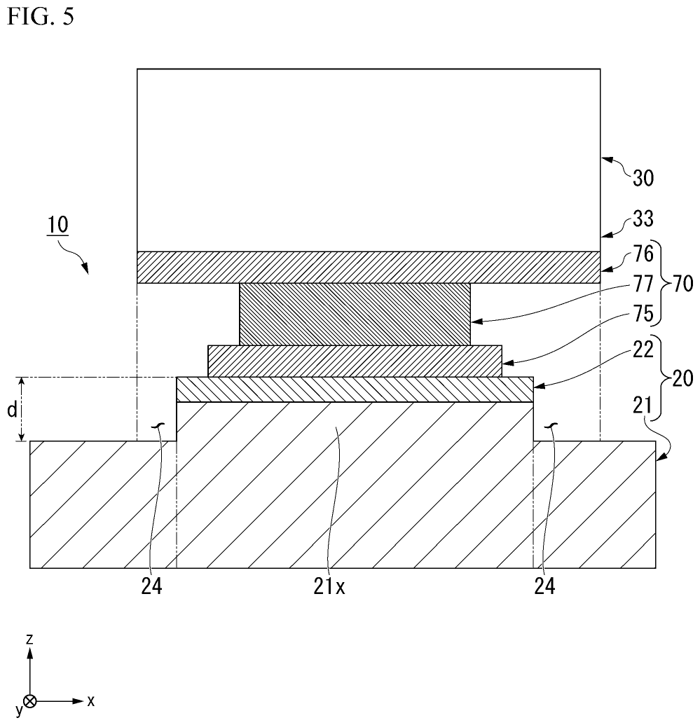

Hereinafter, the subcarriers 10 provided in the laser module 100 will be described. FIG. 4 is an explanatory cross-sectional view of a structure of the subcarriers 10 and the semiconductor light emitting elements (LDs) 30 provided in the laser module 100 in FIG. 1, and FIG. 5 is an explanatory cross-sectional view of a structure of the subcarriers 10 and the semiconductor light emitting elements 30 provided in the laser module 100 in FIG. 1. The cross-sectional view of FIG. 5 is a cross-sectional view illustrating a cross section orthogonal to that of FIG. 4. For the sake of description, FIG. 4 also illustrates a laser L emitted due to induced emission from the LDs 30.

Each of the subcarriers 10 is a subcarrier for a laser module and includes the wafer portion 20 that is constituted of a base 21 and a protective layer 22 formed on a surface of the base 21, a first metal layer 75 that is formed on the protective layer 22, a eutectic layer 77 that is formed on the first metal layer 75, and a second metal layer 76 that is formed on the eutectic layer 77. The wafer portion 20 has a recessed portion(recess) 23 formed in a region overlapping the eutectic layer 77 in the width direction and outside the first metal layer 75 in the longitudinal direction. In the present embodiment, the first metal layer 75, the eutectic layer 77, and the second metal layer 76 will be generically referred to as the metal layers 70.

### (Wafer Portion)

The wafer portion 20 includes the base 21 and the protective layer 22 formed on the surface of the base 21. For example, the base 21 is a wafer constituted using Si or the like. For example, the protective layer 22 is a Si oxide film, a thermal Si oxide film, Si nitride, a tetraethyl orthosilicate (TEOS) film, or the like. For example, the protective layer 22 is constituted using an insulating material such as SiOₓ, Si₃N₄, or TEOS. The protective layer 22 plays a role of electrically isolating the base 21 from the LDs 30. The base 21 has a projection portion 21x protruding in the positive z direction compared to other regions.

In a plan view in a lamination direction (z direction), a part in the vicinity of an end portion of the base 21 in the x direction is exposed. Hereinafter, in an exposed region in the base 21 in a plan view, a region positioned on a side closer to the substrate 40 than the protective layer 22 will be referred to as a first region 211, and a region positioned on a side farther from the substrate 40 than the protective layer 22 will be referred to as a second region 212. That is, in a plan view, the protective layer 22 is positioned between the first region 211 and the second region 212.

For example, the protective layer 22 is formed in an island shape in a plan view. That is, for example, the protective layer 22 is surrounded by the base 21 in a plan view. In other words, in the subcarriers 10, for example, the base 21 is exposed except for a region overlapping the protective layer 22 in a plan view. For example, the protective layer 22 is formed on the projection portion 21x. The shape of the protective layer 22 in a plan view is the same as the shape of the projection portion 21x.

For example, through a step of etching processing after a protective layer is formed on a base, the wafer portion 20 is formed by removing a part of the protective layer and the base. The wafer portion 20 has a structure in which a part of the base is exposed through the step. For this reason, as illustrated in FIGS. 4 and 5, in the base 21, the exposed region in a plan view is recessed portions 23 and 24 having a recessed shape. Hereinafter, in the present embodiment, in order to distinguish the recessed portion positioned in the x direction with respect to the protective layer 22 from the recessed portion 23 positioned in the y direction with respect to the protective layer 22, it may be referred to as a preliminary recessed portion 24. The recessed portion positioned in the x direction with respect to the protective layer 22 and positioned in the y direction with respect to the protective layer 22 will be referred to as the recessed portion 23.

Depths d of the recessed portion 23 and the preliminary recessed portion 24 from a main surface of the protective layer 22 are preferably 10 μm or longer, for example. Due to the recessed portion 23 and the preliminary recessed portion 24 formed to have such a depth, a molten material from the eutectic layer 77 (which will be described below) is controlled such that it is solidified in the recessed portions 23 and 24, and it is easy to achieve an effect of curbing solidification of the molten material on laser light irradiation surfaces of the LDs 30.

### (Metal Layer)

The LDs 30 are bonded to the protective layer 22 from above with the metal layers 70 therebetween. As described above, each of the metal layers 70 includes the first metal layer 75, the eutectic layer 77, and the second metal layer 76. The first metal layer 75 is provided on the wafer portion 20.

For example, the first metal layer 75 is constituted using one or a plurality of metals selected from the group consisting of gold (Au), platinum (Pt), silver (Ag), indium (In), nickel (Ni), titanium (Ti), tantalum (Ta), and tungsten (W). For example, the first metal layer 75 can be formed by a known technique such as sputtering, vapor deposition, or pasted metal coating.

For example, the eutectic layer 77 is constituted using a eutectic body such as AuSn or AuIn. For example, the eutectic layer 77 is constituted using the elements included in the first metal layer 75 and the elements included in the second metal layer 76.

For example, the second metal layer 76 is constituted using one or a plurality of metals selected from the group consisting of gold (Au), platinum (Pt), silver (Ag), lead (Pb), indium (In), and nickel (Ni). For example, the second metal layer 76 can be formed by a known technique such as sputtering, vapor deposition, or pasted metal coating.

For example, the first metal layer 75, the eutectic layer 77, and the second metal layer 76 are formed to have the longitudinal direction in the y direction. For example, the end surfaces of the first metal layer 75 and the eutectic layer 77 in the longitudinal direction are positioned on a side closer to the center than the end surface in a plan view in the longitudinal direction of the second metal layer 76. In addition, it is preferable that the end surface of the first metal layer 75 and the end surface of the eutectic layer 77 be positioned on a side closer to the center in a plan view compared to the end surfaces of the LDs 30. In addition, for example, the end surface of the eutectic layer 77 in the longitudinal direction is positioned on a side closer to the center than the first metal layer 75 in a plan view.

In the laser light irradiation direction (y direction) of the LDs 30, for example, regarding the distance between the end portion of the first metal layer 75 and the end portions of the LDs 30, the end portions of the LDs further protrude than the first metal layer. For example, the foregoing distance may be 1 μm or longer or may be 10 μm or longer. Similarly in the eutectic layer 77 as well, regarding the distance between the end portion thereof and the end portions of the LDs 30 in the y direction, it is preferable to be retreated from the end portion of the first metal layer, for example, 5 μm or longer or 7 μm or longer. Due to the foregoing constitution, blocking of laser light from the laser light irradiation surfaces of the LDs 30 can be curbed, and reflection of laser light by the wafer portion 20 can be curbed. In addition, since the first metal layer 75 and the eutectic layer 77 are sufficiently away from the end portions of the LDs 30 in the y direction, a region in which a molten material of the eutectic layer 77 is formed can be sufficiently secured, and intrusion thereof on the end surfaces of the LDs 30 in the y direction can be curbed.

It is preferable that the end surfaces of the first metal layer 75 and the eutectic layer 77 in the longitudinal direction be provided on an inward side of the recessed portion 23 in a plan view. That is, it is preferable that the end surface of the eutectic layer 77 in the positive y direction be positioned in the negative y direction from the recessed portion 23 in the positive y direction, and it is preferable that the end surface of the eutectic layer 77 in the negative y direction be positioned in the positive y direction from the recessed portion 23 in the negative y direction.

Since the first metal layer 75 and the eutectic layer 77 have the foregoing structure, when a molten material is generated in the eutectic layer 77, a situation in which a molten material moves along the second metal layer 76 and is fixedly attached to the emission surfaces 31 of the LDs 30 can be curbed, and a molten material can be controlled to be formed on a side closer to the recessed portion 23 with respect to the eutectic layer 77. Since a situation in which a molten material is fixedly attached to the emission surfaces 31 of the LDs 30 is curbed, blocking of laser light from the LDs 30 by a molten material is curbed, and thus reliability of the laser module is improved.

In addition, it is preferable that the end surfaces of the first metal layer 75 and the eutectic layer 77 be positioned on the inward side of the end surfaces of the LDs 30 in the x direction as well. That is, in a plan view, it is preferable that the first metal layer 75 and the eutectic layer 77 be covered by the LDs 30. According to the constitution, a situation in which a molten material is fixedly attached to the side surfaces of the LDs 30 in the x direction can also be curbed.

In FIGS. 4 and 5, a constitution in which only the first metal layer 75, the eutectic layer 77, and the second metal layer 76 are formed between the wafer portion 20 and the LDs 30 has been described as an example, but the present embodiment is not limited to the foregoing constitution. For example, from the viewpoint of improving adhesion between a layer constituted using a metal and a different layer, a seed layer constituted using Ti. Ta, or the like, or a barrier layer constituted using Ti, Ta, Ni, Pt, or the like may be formed between the layers.

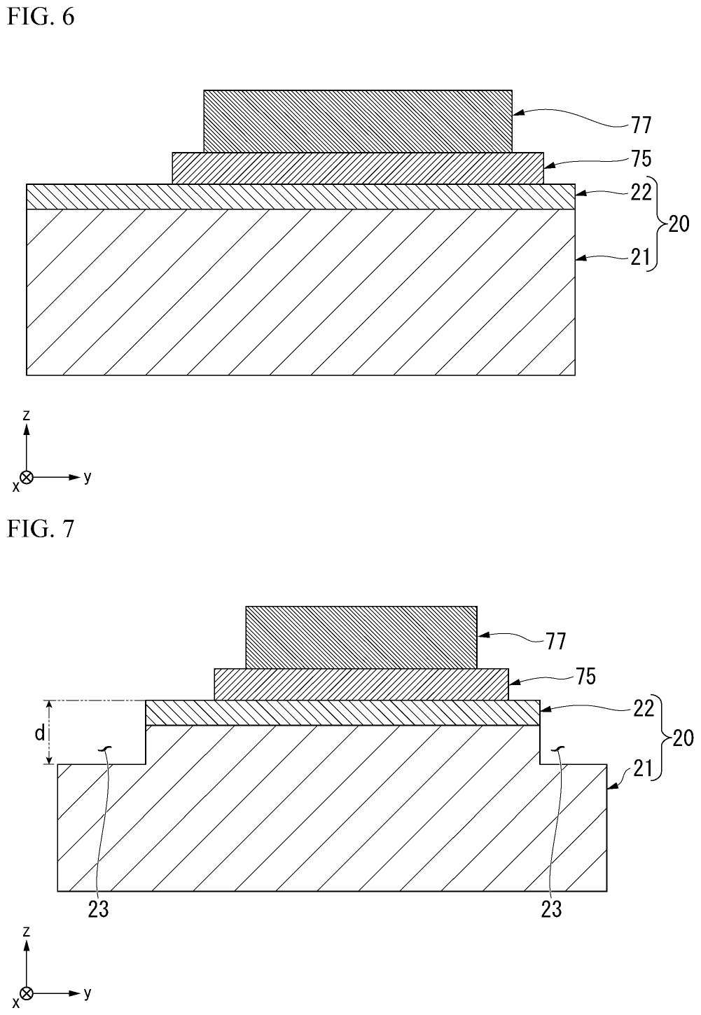

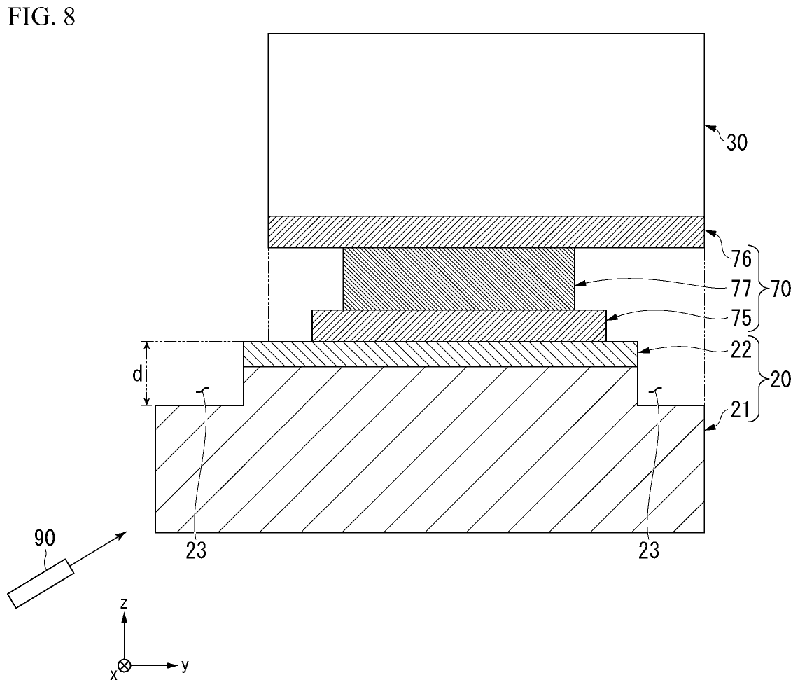

Hereinafter, a method for forming the structure illustrated in FIGS. 4 and 5 will be described with reference to FIGS. 6 to 8. FIG. 6 is an explanatory view of a method for manufacturing a subcarrier according to the embodiment of the present invention and is a view illustrating a condition in which the protective layer 22, the first metal layer 75, and the eutectic layer 77 are formed on the base 21. FIG. 7 is an explanatory view of the method for manufacturing a subcarrier according to the embodiment of the present invention and is a view illustrating a condition in which the recessed portion 23 is formed in the wafer portion 20. FIG. 8 is an explanatory view of the method for manufacturing a subcarrier according to the embodiment of the present invention and is a view illustrating a condition in which the LDs 30 is bonded to the base 21.

For example, the method for manufacturing a subcarrier according to the present embodiment has a lamination step and an etching step. Thereafter, when a laser module is manufactured, a method further having an LD lamination step and a laser light irradiation step is performed.

First, an intermediate structure is produced by sequentially forming the protective layer 22, the first metal layer 75, and the eutectic layer 77 on the base 21 by vapor deposition or the like (FIG. 6, the lamination step).

Next, with respect to the foregoing intermediate structure, a predetermined position is processed by etching or the like, and the recessed portion 23 recessed from the main surface of the wafer portion 20 is formed at a predetermined position in the wafer portion 20 (FIG. 7, the etching step). In the etching step, a preliminary recessed portion 24A may also be formed together with the recessed portion 23. A subcarrier is manufactured in this manner.

Next, a method for manufacturing a laser module will be described. First, for example, with respect to the foregoing intermediate structure having the recessed portion 23 formed therein, the LDs 30 having the growth layers 33 formed on surfaces thereof are laminated with the second metal layers 76 therebetween. Moreover, the first metal layer 75, the eutectic layer 77, and the second metal layer 76 are softened or melted due to heat transfer from the subcarriers 10 by irradiating the subcarriers 10 with laser light from a laser device 90, and thereafter, they are cooled. In a process of manufacturing a laser module in the related art, there is concern that a molten material may excessively spread in the in-plane direction and be fixedly attached to the side surfaces of the LDs 30. However, in the laser module according to the present embodiment, since the recessed portion 23 or the recessed portion 23 and the preliminary recessed portion 24A are formed on a side opposite to the LDs 30 with respect to the eutectic layer 77, a molten material is selectively formed in the recessed portion 23 and the preliminary recessed portion 24, and a situation in which it is fixedly attached to the side surfaces of the LDs 30 can be curbed.

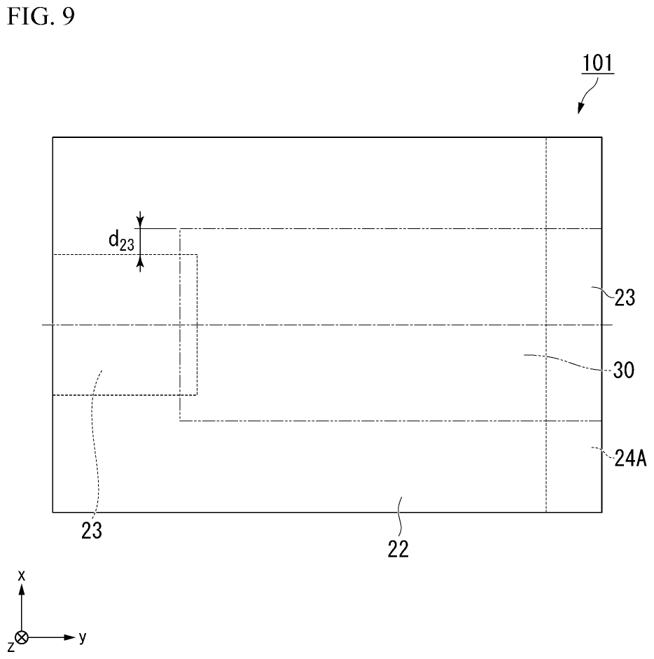

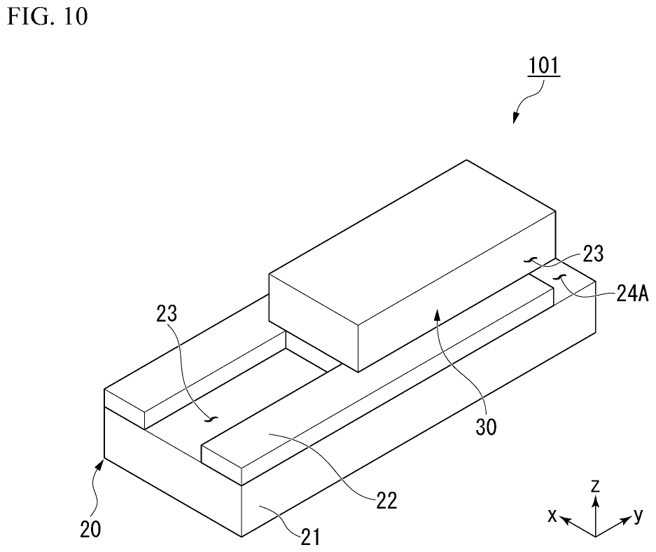

In addition, in the foregoing embodiment, an example in which the recessed portion 23 and the preliminary recessed portion 24A are formed in the wafer portion 20 and the protective layer 22 has an island-shaped structure surrounded by the base 21 in a plan view has been described, but the present invention is not limited to this example. FIG. 9 is a top view illustrating a modification example of the laser module in in FIG. 1, and FIG. 10 is a perspective view illustrating the modification example of the laser module in FIG. 1. In FIGS. 9 and 10, for the sake of description, only the wafer portion 20 and the LD 30 are illustrated in an enlarged manner, and illustration of members such as the metal layer 70 formed between the wafer portion 20 and the LD 30 is omitted. In FIG. 9, regions in the wafer portion 20 having the recessed portion 23 and the preliminary recessed portion 24A formed therein are indicated by dotted lines, a region having the LD 30 installed therein is indicated by a two-dot dashed line, and a centerline corresponding to the center of the LD 30 in the width direction is indicated by a one-dot dashed line. As illustrated in FIGS. 9 and 10, in a laser module 101, the preliminary recessed portion 24A is formed in a region overlapping the end portion in the emission direction and regions in the positive and negative x directions of the region overlapping the end portion.

In the x direction, a distance d₂₃ between an end surface of a laser diode 30 and the recessed portion 23 is 5 μm to 50 μm, for example, and may be 5 μm to 15 μm.

The preliminary recessed portion 24A is formed in the width direction (x direction) orthogonal to the irradiation direction (y direction) of laser light in the in-plane direction (xy direction) of the LD 30 in a region of 10 μm to 50 μm, for example, from the end surface of the LD 30 in the x direction and is preferably formed in a region of 15 μm to 25 μm. In addition, it is preferable that the preliminary recessed portion 24A be formed throughout a region of at least 5 μm or longer from the end portion of the LD 30 in the x direction. The preliminary recessed portion 24A is sufficiently large in the width direction, which is desirable from the viewpoint of preventing an adverse effect caused by a sticking-out molten metal of the metal constituting the eutectic layer 77.

In addition, in the laser module 101, similar to the laser module 100, the recessed portion 23 is formed at a position in the negative y direction with respect to the LD 30. In the laser module 101, since the recessed portion 23 and the preliminary recessed portion 24A are formed in contact with the end portions of the LD 30 in the positive and negative y directions, formation of a molten material of the protective layer 22 and the eutectic layer 77 on the end surface of the LD 30 in the y direction is curbed, and thus blocking of laser light can be curbed.

In addition, according to the laser module 101 illustrated in FIGS. 9 and 10, since the preliminary recessed portion 24A is formed, a situation in which laser light Lis blocked by a sticking-out molten metal of the metal constituting the eutectic layer 77 and a sticking-out and swelling molten metal interferes with other components and flows into a bonding portion with respect to other components is curbed.

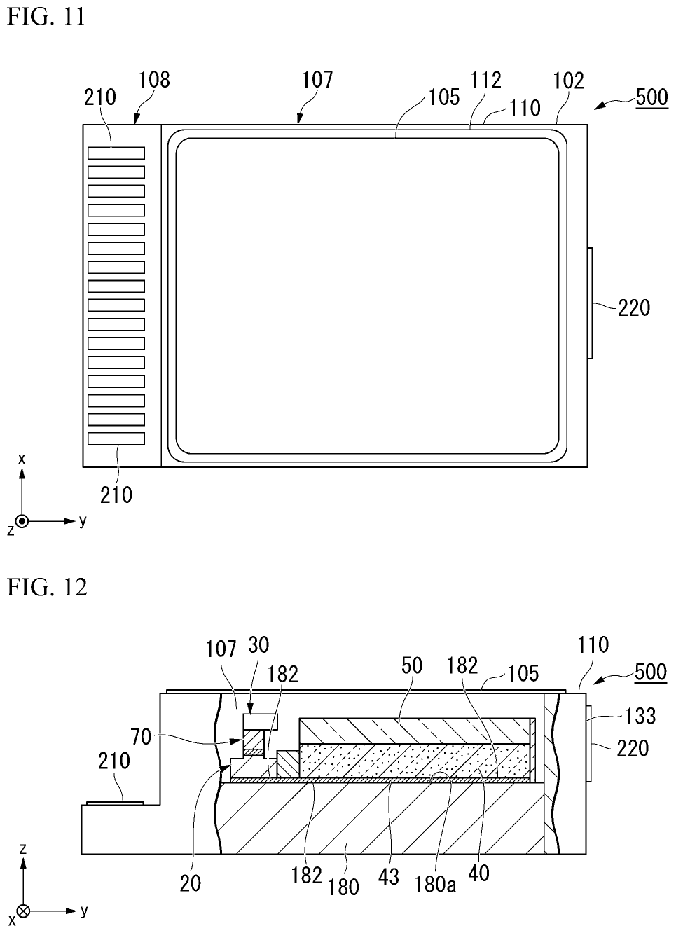

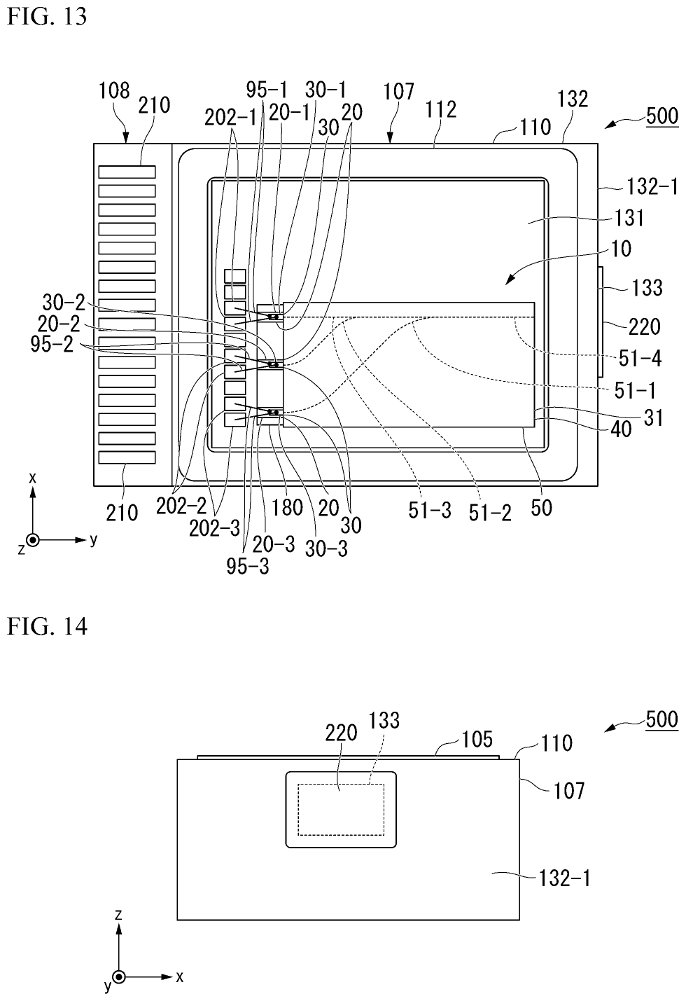

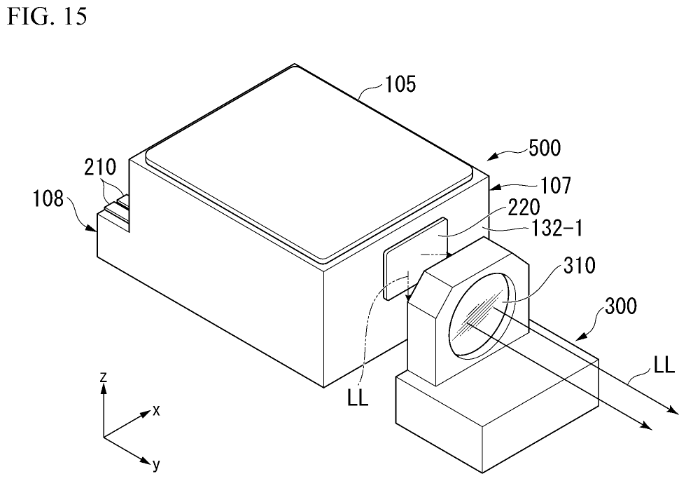

The laser module according to the foregoing embodiment may be accommodated in a package. FIGS. 11 to 15 illustrate a packaged laser module 500. FIG. 11 is a plan view of a packaged laser module. FIG. 12 is a cross-sectional view of the laser module in FIG. 11. FIG. 13 is a plan view of a state in which a cover of the laser module in FIG. 11 is removed. FIG. 14 is a side view of the laser module in FIG. 11 viewed from an emission portion side. FIG. 15 is a perspective view illustrating a form when the laser module in FIG. 11 is in use. For example, the laser module 500 includes a package 110, and the laser module 100 according to the foregoing embodiment is integrated and accommodated therein. The package 110 includes a main body 102 having a cavity structure, and a cover 105 covering the main body 102.

For example, the main body 102 includes a box-shaped accommodation portion 107 accommodating the laser module 100, and an electrode portion 108 formed to be adjacent to the accommodation portion 107. For example, the main body 102 is constituted using ceramic or the like. An opening is formed on an upper surface of the accommodation portion 107. A metal film 112 of Kovar or the like is formed on the upper surface of the accommodation portion 107 of a circumferential edge of the opening in a top view. The cover 105 tightly covers the opening formed on the upper surface of the accommodation portion 107 with the metal film 112 therebetween. When the accommodation portion 107 is airtightly sealed with the cover 105, inert gas such as nitrogen (N₂) is enclosed in an internal space of the accommodation portion 107. That is, the accommodation portion 107 is airtightly sealed by the cover 105. The internal space of the accommodation portion 107 is filled with inert gas. Accordingly, a gap between the LD 30 and the PLC 50 is filled with inert gas.

The electrode portion 108 is disposed in the negative y direction with respect to the accommodation portion 107. That is, the electrode portion 108 is provided in a direction opposite to a laser emission direction from the emission surface 31 of the LD 30. A bottom surface of the electrode portion 108 is positioned substantially at the same height as the bottom surface of the accommodation portion 107. A plurality of external electrode pads 210 are provided on an upper surface of the electrode portion 108 with an interval therebetween in the x direction.

For example, a substructure 180 for installing the laser module 100 is provided at a predetermined position in a bottom wall portion 131 of the accommodation portion 107. For example, the laser module 100 is provided on the substructure with an adhesive layer 182 having high thermal conduction therebetween. For example, for the adhesive layer 182, a resin having a filler such as copper powder, aluminum powder, or alumina powder dispersed therein is used. If the laser module 100 is installed as described above, heat generated due to operation of the LD 30 can be efficiently dissipated toward the substructure 180. In FIG. 13, an example in which the laser module 100 is provided on the integrated substructure 180 has been described, but a member in contact with the wafer portion 20 and a member in contact with the substrate 40 may be formed on separate substructures. In addition, the laser module 100 may be directly formed in the accommodation portion 107 without being provided on the substructure 180.

An example of a constitution in which the bottom surfaces of the subcarriers 10 and the bottom surface of the substrate 40 are in the same plane has been described, but the present embodiment is not limited to the foregoing constitution. There is no need for the bottom surfaces of the subcarriers 10 and the bottom surface of the substrate 40 to be flush with each other, and a step may be provided between the bottom surfaces of the subcarriers 10 and the bottom surface of the substrate 40.

### [XR Glasses][Optical Engine Module]

In XR glasses according to the present embodiment, any laser module according to the foregoing embodiment is mounted in the glasses. The XR glasses (eyeglasses) are an eyeglass-type terminal, and XR is a general term of virtual reality (VR), augmented reality (AR), and mixed reality.

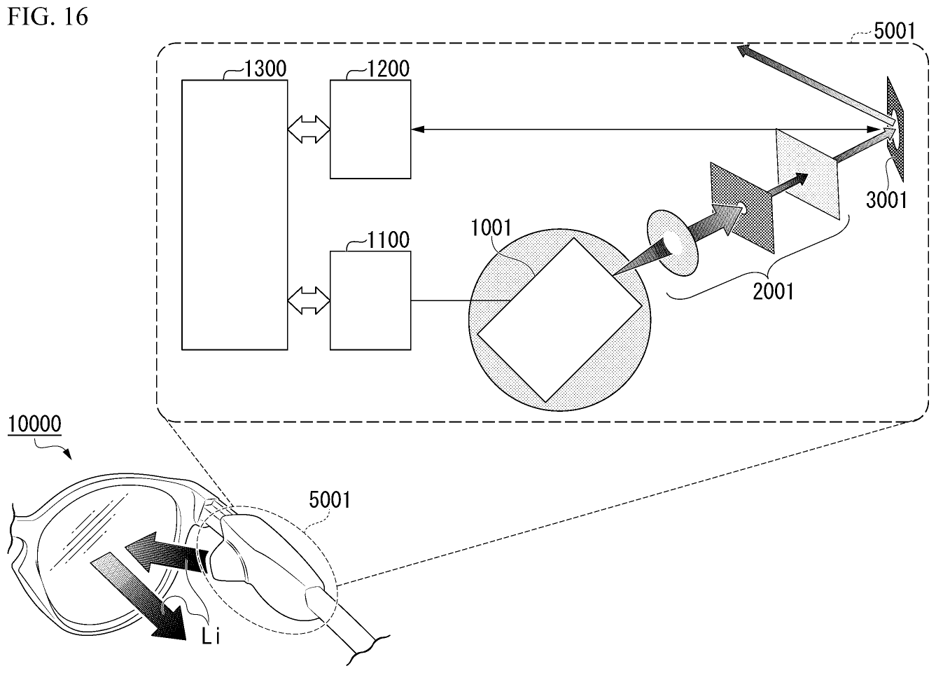

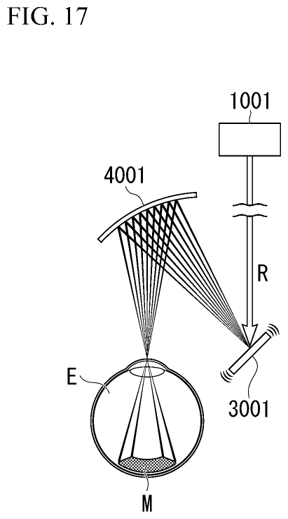

FIG. 16 is an explanatory conceptual view of XR glasses according to the embodiment of the present invention. In XR glasses 10000 illustrated in FIG. 16, a laser module 1001 is mounted in a frame 10010. The reference sign Li in FIG. 16 indicates image display light. In addition, FIG. 17 is a conceptual view illustrating a condition in which an image is directly projected onto the retina by laser light emitted from the laser module according to the embodiment of the present invention.

In the present embodiment, the laser module 1001, an optical scanning mirror 3001, and an optical system 2001 connecting the laser module 1001 and the optical scanning mirror 3001 to each other will be collectively referred to as an optical engine module 5001 (illustrated in FIG. 16). The laser module according to the foregoing embodiment can be used as the laser module 1001.

For example, a light source having RGB laser light sources including a red laser light source 60-1, a green laser light source 60-2, and a blue laser light source 60-3, and a near-infrared laser light source can be used as the light source of the laser module 1001.

As illustrated in FIG. 17, the laser L for irradiation from the laser module 1001 attached to an eyeglass frame is reflected by the optical scanning mirror 3001. The reflected light is reflected by a mirror 4001 reflecting light in a direction of the eyeball E of a human and enters the inside of the eyeball E of the human so that an image (video image) can be directly projected onto the retina M.

The optical engine module includes an eye-tracking mechanism so that an image is directly projected onto the retina while eye-tracking is performed. A known mechanism can be used as the eye-tracking mechanism.

For example, the optical scanning mirror 3001 is a MEMS mirror. In order to project a 2D image, it is preferable that the optical scanning mirror 3001 be a 2-axis MEMS mirror which oscillates such that laser light is reflected while varying the angle in the horizontal direction (X direction) and the vertical direction (Y direction).

For example, the optical engine module includes a collimator lens 2001a, a slit 2001b, and an ND filter 2001c as the optical system 2001 for optically processing laser light emitted from the laser module 1001. The foregoing optical system is an example, and the optical system 2001 may have a different constitution.

The optical engine module 5001 includes a laser driver 1100, an optical scanning mirror driver 1200, and a video controller 1300 controlling these drivers.

According to the optical engine module of the foregoing embodiment, blocking of an irradiation surface of an optical semiconductor element by a structure formed by melting is curbed. In addition, return of light from a laser light emitting point to the light emitting point is curbed, and reliability of irradiation with the laser Lis improved.

While preferred embodiments of the invention have been described and illustrated above, it should be understood that these are exemplary examples of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

### Appendix

(a) XR glasses according to another aspect of the present disclosure include the optical engine module according to the aspect described in (7) above.

### EXPLANATION OF REFERENCES

10, 10-1, 10-2, 10-3 Subcarrier
11, 11-1, 11-2, 11-3 Upper surface
20 Wafer portion
21 Base
22 Protective layer
23 Recessed portion
24 Preliminary recessed portion
30 Semiconductor light emitting element (LD)
31, 31-1, 31-2, 31-3 Emission surface
33 Growth layer
40 Substrate
41 Upper surface
51, 51-1, 51-2, 51-3, 51-4, 51-7 Core
52 Cladding
57-1, 57-2 Merged position
60-1 Red laser light source
60-2 Green laser light source
60-3 Blue laser light source
61, 61-1, 61-2, 61-3 Incidence surface
64 Emission surface
70 Metal layer
75 First metal layer
76 Second metal layer
77 Eutectic layer
81 Antireflection film
90 Laser device
100 Laser module
102 Main body
105 Cover
107 Accommodation portion
108 Electrode portion
110 Package
112 Metal film
131 Bottom wall portion
180 Substructure
182 Adhesive layer
210 External electrode pad
211 First region
212 Second region

What is claimed is:

1. A subcarrier for a laser module comprising:
a wafer portion that is constituted of a base and a protective layer formed on a surface of the base;
a first metal layer that is formed on the protective layer;
a eutectic layer that is formed on the first metal layer; and
a second metal layer that is formed on the eutectic layer,
wherein the wafer portion has a recessed portion formed in a region overlapping the second metal layer in a width direction and outside the first metal layer in a longitudinal direction.

2. The subcarrier according to claim 1,
wherein in a plan view in a lamination direction, end surfaces of the first metal layer and the eutectic layer in the longitudinal direction are positioned on an inward side of an end surface of the base in the longitudinal direction.

3. The subcarrier according to claim 1,
wherein a depth of the recessed portion from a surface of the protective layer is 10 μm or longer.

4. A laser module comprising:
the subcarrier according to claim 1; and
an optical semiconductor element formed on the second metal layer which is configured to irradiate laser light in the longitudinal direction,
wherein in a plan view in a lamination direction, the optical semiconductor element overlaps the recessed portion.

5. The laser module according to claim 4,
wherein the first metal layer and the eutectic layer are covered by the optical semiconductor element.

6. The laser module according to claim 4,
wherein in a laser light irradiation direction of the optical semiconductor element, a distance between an end portion of the first metal layer and an end portion of the optical semiconductor element is 1 μm or longer.

7. An optical engine module comprising:
the laser module according to claim 4; and
an optical scanning mirror that performs scanning with light emitted from the laser module.
